(19) United States
(12) Patent Application Publication
(10) Pub. No.: US 2002/0179000 A1
(43) Pub. Date: Dec. 5, 2002

(54) Method for single crystal growth of perovskite oxides

(76) Inventors: Ho-Yang Lee, Seoul (KR); Jae-Suk Kim, Seoul (KR); Jong-Bong Lee, Choongchung-Nam-Do (KR); Tae-Moo Hur, Kyeongki-Do (KR); Doe-Yeon Kim, Seoul (KR); Nong-Moon Hwang, Seoul (KR)

Correspondence Address: BROWDY AND NEIMARK, P.L.L.C., 624 NINTH STREET, NW, SUITE 300, WASHINGTON, DC, 20001-5303, US

(21) Appl. No.: 09/857,774

(22) PCT Filed: Feb. 22, 2001
(86) PCT No.: PCT/KR01/00267

(30) Foreign Application Priority Data
Feb. 23, 2000 (KR) 2000/8916
Feb. 21, 2001 (KR) 2001/8685

(51) Int. Cl. C30B 1/00; C30B 3/00; C30B 5/00; C30B 28/02

(52) U.S. Cl. 117/4

(57) ABSTRACT

The invention relates to a method for growing single crystals of Perovskite Oxides. The method is characterized by comprising the steps of (a) contacting a Perovskite seed single with a Perovskite polycrystal and (b) heating the contacted crystals to grow the same structure as the single crystal into the polycrystal, the heating is controlled under conditions which abnormal grains growth is induced in the contacted portion while repressed in the inside of the polycrystal. The method for growing single crystals of Perovskite Oxides according to this invention has an advantage to provide an effective low cost in manufacturing process for single crystals by using usual heat-treatment process without special equipments. The method for growing single crystals of Perovskite Oxides according to this invention can be also applicable to other material systems showing abnormal grain growth behavior.

### BACKGROUND OF THE INVENTION

1. Field of the Invention

The present invention relates to a method for growing single crystals of perovskite oxides and, more particularly, to a method for growing single crystals characterized in that a perovskite seed single crystal such as barium titanate(BaTiO₃) is adjoined to a polycrystal of perovskite oxides and then the adjoined combination is heated, to grow the same structure as the seed single crystal in the polycrystal by causing abnormal grain growths at the interface between the seed single crystal and the polycrystal, thereby allowing the single crystal of perovskite oxides to have the same composition as the polycrystal to which the seed single crystal is originally adjoined as well as the same crystallographic structure as the seed single crystal. In addition, the invention relates to a method for producing on a large scale by using the single crystal produced according to the above method as a seed single crystal.

2. Description of the Related Art

The “perovskite oxides” as used herein have a chemical formula of “ABO₃”, e.g., BaTiO₃. In Pb-type perovskite oxides, Pb substitutes for entire or a portion of “A” of the above formula, e.g., “(PbₓA₁₋ₓ)BO₃” (0≦x≦1) of a simple form or “(PbₓA₁₋ₓ)(B_{y}C_{1-y})O₃” (0≦x≦1; 0≦y≦1), in which the number of the atoms substituting for “A” or “B” increases. Pb-type perovskite oxides include PbTiO₃(PT), (Pb,Ba)TiO₃, Pb(ZrₓTi₁₋ₓ)O₃((PZT), Pb(Mg_{⅓}Nb_{⅔})O₃ (PMN), (1−x)PMN−xPT, (1−x−y)PMN−xPT−yPZ, Pb(Zn_{⅓}Nb_{⅔})O₃(PZN) or (1−x)PZN−xPT, (1−x−y)PZN−xPT−yPZ, etc.

The single crystals of perovskite oxides are widely applied in various fields, including optical, piezoelectric, electric or mechanical field, etc., and the application fields will be extended with industry development.

The single crystals of undoped barium titanate and barium titanate solid solution are widely used as a material for piezoelectric devices and optical devices such as optical valve, optical interrupter, and phase-matching mirror, etc. and considered as a promising substrate material for various thin film elements. In Pb-type perovskite oxides, particularly, the single crystals of Pb(ZrₓTi₁₋ₓ)O₃(PZT), (1−x)Pb(Mg_{⅓}Nb_{⅔})O₃−xPbTiO₃(PMN-PT) or (1−x)Pb(Zn_{⅓}Nb_{⅔})O₃−xPbTiO₃(PZN), etc. and the solid solution thereof are considered as promising materials for electronic devices, because of their high dielectric and excellent piezoelectric properties such as remarkable electro-mechanical coupling factors.

The conventional methods for growing a single crystal of barium titanate (BaTiO₃), barium titanate solid solution, Pb-type perovskite and Pb-type perovskite solid solution require expensive facilities, however, involves many problems in producing a large amount of big single crystals because of extremely complicated process for growing the single crystals and have difficulty in the application because of the high expense. In particular, Pb-type perovskite oxides have serious problems because lead oxide(PbO) having a strong volatility volatilizes when single crystals grow. Further, the conventional methods for growing a single crystal of Pb-type perovskite oxides and the solid solution thereof necessarily require a melting process, and thus make the entire composition change and the phase of the perovskite unstable owing to the volatilization of PbO. Therefore, it is difficult to produce a single crystal having a desired size and property. In addition, it is difficult to produce in large quantities because of the difficulty in the production processes and the requirement of expensive facilities.

Since the emergence of Flux method for single crystal growth of (1−x)Pb(Mg_{⅓}Nb_{⅔})O₃−xPbTiO₃(PMN-PT), the subsequent methods for single crystal growth have been developed such as the Bridgman Method, etc. However, these general methods such as Flux Method or Bridgman Method using a melting process, etc. present some problems in the production of PMN-PT single crystal in that it is difficult to maintain the uniform composition of the growing single crystal owing to the volatilization of PbO during the melting process. Therefore, the processes require complex facilities and skilled functions and are difficult to produce single crystals in large quantities at low costs.

The production of single crystals of Pb(ZrₓTi₁₋ₓ)O₃(PZT) having an actually applicable size by general liquid-state single crystal growth methods is considered to be impossible, because of the difficulty in repression of the strong volatilization of PbO and the separation to liquid phase and ZrO₂ during melting, i.e., Incongruent Melting. In case of the mass production of single crystals of PZT, which is one of materials having the most excellent piezoelectric property, the produced PZT can substitute for the conventional piezoelectric polycrystal and materials for single crystals in various application fields.

Grain growth takes place during the step of sintering polycrystals, in which case only a few grains are sometimes rapidly grown in an abnormal manner relative to the most normal grains. It is appreciated that controlling the growth of such a few abnormal grains in polycrystals may allow single crystal to be easily produced without a melting process.

A general method for single crystal growth using the melting process is called Liquid-state Single Crystal Growth (LSCG) method, and a method for single crystal growth by heat treatment of polycrystals is referred to as Solid-state Single Crystal Growth (SSCG) method. The SSCG method has been suggested since the 1950's and demonstrated as an effective method of preparing single crystals of a metal, which is limited to only a few types. It is however reported that the method has a difficulty in preparing single crystals large enough for practical use from an oxide, because the growth is too slow in grain growth and hard of controlling nucleation of abnormal grains.

Since the emergence of the Flux method for single crystal growth of barium titanate, the subsequent methods for single crystal growth of barium titanate have been developed such as Zone Melting method and the Top-Seeded Solution Growth (TSSG) method. The single crystals of barium titanate grown by the Flux method have a thickness of less than 1 mm and a diameter of several millimeters and thus actually restrained in practical uses. It is known that the TSSG method, which has the advantages of the Flux method and the Czochralski method, is applicable to the growth of relatively large single crystals of barium titanate almost without residual stress. However, the TSSG method also requires complicate facilities and skilled functions and is inadequate as a method for preparing a large amount of single crystals at a low cost.

Meanwhile, there has been made an attempt to obtain single crystals by subjecting polycrystals of ferrite, barium titanate [BaTiO₃], aluminum oxide [Al₂O₃] and PMN-PT to heat treatment through Solid-State Single Crystal Growth(SSCG) Method. This method for single crystal growth involves sintering a powder impregnated with single crystals as seed single crystals or providing an interface between the polycrystals and the seed single crystals, followed by heat treatment. Disadvantageously, the method is not suitable to preparing single crystals large enough for practical uses such as more than several mm because the growth of single crystals is retarded relative to the conventional Liquid-State Single Crystal Growth methods. Even though single crystals are produced by using abnormal grain growth phenomenon occurring in the polycrystal, it is difficult to continue to grow single crystals because the abnormal grains of the polycrystal repress the growth of the seed single crystals when the growing seed single crystals meet peripheral abnormal grains. Therefore, the conventional Solid-State Single Crystal Growth(SSCG) method is less advantageous than the conventional Liquid-State Single Crystal Growth method, in that it is difficult to produce single crystals having an actually applicable large size and the reproduction possibility is low because it is impossible to control the abnormal grain growths occurring inside the polycrystal by the method. In particular, in the case of PMN-PT, it is difficult to produce single crystals having a size of more than several mm because of the trouble in the control of abnormal grain growths in the polycrystal.

For single crystal growth of barium titanate [BaTiO₃], there is reported a method for preparing single crystals by adding particles having a (111) double twin plate or a seed forming agent to form a (111) double twin plate. However, this method also has problems in that it cannot produce single crystals without a (111) double twin plate and cannot produce in large quantities single crystals large enough for practical use at low costs because it is difficult to control secondary abnormal grain growth, create a single crystal and continue to grow only the single crystal.

### SUMMARY OF THE INVENTION

It is, therefore, an object of the present invention is to overcome the problems of the conventional single crystal growth method (i.e., liquid-state single crystal growth method) requiring a melting process, and to provide a method for growing single crystals of undoped barium titanate, barium titanate solid solution, various perovskite oxides, including Pb-type perovskite such as PbTiO₃(PT), Pb(ZrₓTi₁₋ₓ)O₃(PZT), Pb(Mg_{⅓}Nb_{⅔})O₃(PMN), (1−x)PMN−xPT, Pb(Zn_{⅓}Nb_{⅔})O₃(PZN) or (1−x)PZN−xPT perovskite oxide solid solution through Solid-State Single Crystal Growth(SSCG) Method, by effectively controlling abnormal grain growths occurring in polycrystals, only by a general heating process without a special apparatus, thereby allowing the mass production of single crystals at low costs with high reproduction possibility.

To achieve the object of the present invention, there is provided a method for growing single crystals of perovskite oxides, which show abnormal grain growths by means of heating, the method comprising the steps of (a) having a perovskite seed single crystal adjoined to a perovskite polycrystal; and (b) heating the combination of seed single crystal and the polycrystal to provide a continuous growth of the same structure as the seed single crystal in the polycrystal, the heating being carried out under the condition that abnormal grain growths are induced in an interface between the polycrystal and the seed single crystal and are repressed inside the polycrystal.

### BRIEF DESCRIPTION OF THE DRAWINGS

FIG. 1 is an illustration showing a perovskite seed single crystal adjoined to a polycrystal of perovskite oxides in the method of the present invention;

FIG. 2 is microscopic photographs of samples obtained by sintering (a) a powder molded body having the composition formula of (0.68)Pb(Mg_{⅓}Nb_{⅔})O₃−(0.32)PbTiO₃ and (b) a powder molded body having the composition formula of (0.5)Pb(Mg_{⅓}Nb_{⅔})O₃−(0.5)PbTiO₃, at 1200° C. for 10 hours;

FIG. 3 is a microscopic photograph of a sample obtained by sintering a powder molded body having the composition formula of (0.92)[(0.68)Pb(Mg_{⅓}Nb_{⅔})O₃−(0.32)PbTiO₃]−(0.08)MgO, at 1200° C. for 10 hours;

FIG. 4 is a microscopic photograph of a sample obtained by sintering a powder molded body having the composition formula of (0.92)[(0.68)Pb(Mg_{⅓}Nb_{⅔})O₃−(0.32)PbTiO₃]−(0.08)PbO, at 1200° C. for 10 hours;

FIG. 5 is microscopic photographs of samples obtained by sintering powder molded bodies, which are (a) 2% Mg-deficient (−2 Mg), (b) 1% Mg-deficient (−1 Mg), (C) 0% Mg-deficient (0 Mg) and (d) 1% Mg-extra (1 Mg) in the composition formula of (0.92)[(0.68)Pb(Mg_{⅓}Nb_{⅔})O₃−(0.32)PbTiO₃]−(0.08)PbO, at 1200° C. for 10 hours;

FIG. 6 is microscopic photographs of samples obtained by sintering powder molded bodies, which are (a) 2% Mg-deficient (−2 Mg), (b) 1% Mg-extra (1 Mg) in the composition formula of (0.92)[(0.68)Pb(Mg_{⅓}Nb_{⅔})O₃−(0.32)PbTiO₃]−(0.08)PbO, at 1200° C. for 10 hours;

FIG. 7 is microscopic photographs of PMN-PT single crystals grown from samples obtained by embedding a seed single crystal of BaTiO₃, which is a plate-shaped crystal of (a) (100) side, (b) (110) side and (c) (111) side, in powder molded bodies further having 1% extra Mg (1 Mg) in addition to the original Mg content in the composition formula of (0.92)[(0.68)Pb(Mg_{⅓}Nb_{⅔})O₃−(0.32)PbTiO₃]−(0.08)PbO, and then heating the combination at 1200° C. for 10 hours;

FIG. 8 is a microscopic photograph of a PMN-PT single crystal (diameter: 1.5 cm) grown from samples obtained by embedding a seed single crystal of BaTiO₃ in powder molded bodies further having 1% extra Mg (1 Mg) in addition to the original Mg content in the composition formula of (0.92)[(0.68)Pb(Mg_{⅓}Nb_{⅔})O₃−(0.32)PbTiO₃]−(0.08)PbO, and then heating the combination at 1200° C. for 20 hours;

FIG. 9 is microscopic photographs of samples obtained by sintering powder molded bodies having x value of (a) 0.6 and (b) 0.25 in the composition formula of (0.9)[Pb(ZrₓTi₁₋ₓ)O₃]−(0.1)PbO, at 1200° C. for 3 hours;

FIG. 10 is a microscopic photograph a sample obtained by embedding a seed single crystal of BaTiO₃ in a powder molded body having the composition formula of (0.9)[Pb(Zr_{0.25}Ti_{0.75})O₃]−(0.1)PbO, and then sintering the combination at 1200° C. for 10 hours;

FIG. 11 is a microscopic photograph a sample obtained by embedding a seed single crystal of BaTiO₃ in a powder molded body having the composition formula of (0.9)[Pb(Zr_{0.6}Ti_{0.4})O₃]−(0.1)[(0.95)PbO−(0.05)Cr₂O₃], and then sintering the combination at 1200° C. for 10 hours;

FIG. 12 is microscopic photographs of samples obtained by sintering powder molded bodies having the composition formula of (a) Pb(Zr_{0.52}Ti_{0.48})O₃ and (b) (0.7)Pb(Zr_{0.52}Ti_{0.48})O₃−(0.3)PbZrO₃, at 1200° C. for 1 hour;

FIG. 13 is a microscopic photograph showing a PZT single crystal grown from a sample obtained by embedding a seed single crystal of BaTiO₃, which is a plate-shaped crystal of (111) side, in a powder molded body having the composition formula of (0.8)[Pb(Zr_{0.52}Ti_{0.48})O₃]−(0.2)PbZrO₃, and then heating the combination at 1200° C. for 10 hours;

FIG. 14 is a microscopic photograph showing a single crystal grown from a sample obtained by placing a small seed single crystal (diameter: 3 mm, thickness: 1.5 mm) on the edge of a polycrystal of barium titanate, and then heating the combination for 300 hours under the condition of a temperature gradient, which is 1350° C. on the side of the seed single crystal and a decreased temperature of slightly below 1350° C. on the opposite edge side of the sample;

FIG. 15 is a microscopic photograph showing the appearance of a sample prepared by placing a single crystal of barium titanate including a (111) double twin plate on a polycrystal of barium titanate, and then heating the combination for 15 hours at 1350° C.;

FIG. 16 is microscopic photographs showing the surface(a) and the cross section(b) of a sample prepared by placing a single crystal of barium titanate on a molded body and then heating at 1350° C. for 50 hours, wherein the molded body is formed by laminating in a row three powders(each thickness: 1.5 mm) having the composition formulas of (99.9)BaTiO₃−(0.1)MnO₂(mol %); (99.9)BaTiO₃−(0.1)NbO_{2.5}(mol %); and (99.9)BaTiO₃−(0.1)CeO₂(mol %).

### DETAILED DESCRIPTION OF THE PREFERRED EMBODIMENTS

Hereinafter, preferred embodiments of a method for growing single crystals of perovskite oxides according to the present invention will be described in detail with reference to the accompanying drawings.

A method for growing single crystals of perovskite oxides according to this invention includes adjoining a seed single crystal of perovskite oxides, which shows abnormal grain growths by means of heating, to a perovskite polycrystal and then heating the combination of seed single crystal and the polycrystal in order to allow the same structure as the seed single crystal to continue to be grown in the polycrystal. The single crystal of perovskite oxides obtained by the above method has the same composition as the original polycrystal and the same structure as the seed single crystal. This single crystal is herein referred to “a single crystal having the composition of the polycrystal”.

The single crystals having various compositions produced according to this invention can be used as a seed single crystal in another method. In other words, single crystals can be produced by adjoining a single crystal produced according to this invention to a polycrystal, and then allowing a single crystal having the same structure as the seed single and the same composition as the polycrystal to continue to be grown. This recycling of single crystals can reduce the cost for production of single crystals.

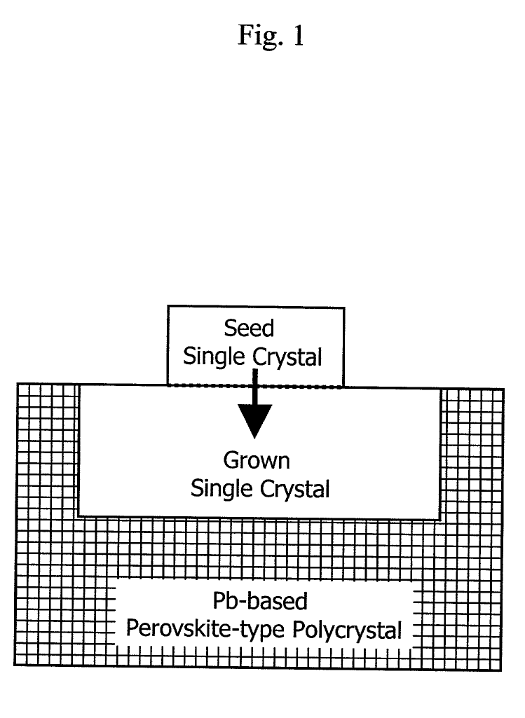

FIG. 1 is an illustration showing a perovskite seed single crystal (the primary seed single crystal is a single crystal of barium titanate) adjoined to a polycrystal of perovskite oxides in the method of the present invention.

As shown in FIG. 1, the adjoining of a seed single crystal to a polycrystal includes placing the seed single crystal on the polycrystal or the powder molded body, embedding the seed single crystal in the powder molded body, or embedding the combination of the seed single crystal and the polycrystal in the powder molded body.

Further, the method according to this invention is characterized in that the growth of the seed single crystal is promoted by using a plate-shaped or a “ [symbol] ”-shaped seed single crystal and thus increasing the number of the adjoined side of the polycrystal and the seed single crystal.

In perovskite oxides, including Pb-type perovskite oxides, an abnormal grain growth takes places by composition changes of powders, formations of temperature gradients or local additions of additives during heating, etc. In addition, the abnormal grain growth activating temperature, the size and the number of the abnormal grains are affected by the composition changes of the powders, the formation of temperature gradients or the local additions of additives, etc. In the method according to this invention, the abnormal grain growth is repressed inside the polycrystal and is induced at the interface between the seed single crystal and the polycrystal by the composition changes of the powders, the formation of temperature gradients or the local additions of additives, etc., to grow single crystals having the same structure as the seed single crystal in the polycrystal. In particular, the abnormal grain growth in the polycrystal is controlled by controlling the component ratio of the polycrystal or adding excess specific components of the polycrystal. Under the above conditions, the abnormal grain growth is repressed inside the polycrystal and is induced at the interface between the seed single crystal and the polycrystal through a heat treatment.

Further, the abnormal grain growth is controlled by continuing to heat the combination of the seed single crystal and the polycrystal such that the temperature of the interface of the seed single crystal and the polycrystal is higher than the temperature of the polycrystal inside, and thus inducing the growth at the interface between the seed single crystal and the polycrystal and repressing inside the polycrystal.

Further, additives for promoting an abnormal grain growth are added to the interface between the seed single crystal and the polycrystal in heat treatment, so as to rapidly grow a single crystal having the same structure as the seed single crystal and having a large size enough for a practice use. Said additives for promoting an abnormal grain growth by lowering the abnormal grain growth activating temperature are preferably one or more additives selected from the group consisting of Al₂O₃, B₂O₃, CuO, GeO₂, Li₂O₃, P₂O₅, PbO, SiO₂ and V₂O₅.

The method for single crystal growth according to this invention is characterized in that a perovskite single crystal having a large size of more than several cm is produced by an abnormal grain growth occurring at the interface between a seed single crystal and a polycrystal, and is produced by adjoining the single crystal prepared above as a seed single crystal to a polycrystal and then heating, to continue to grow a single crystal having the same structure as the seed crystal in the polycrystal.

In the method according to this invention, said heating temperature is slightly lower than the abnormal grain growth activating temperature so that only the seed single crystal can be grown while the abnormal grain growths of single crystals other than the seed single crystal are repressed.

In the method according to this invention, the polycrystal of perovskite oxides is characterized in that one or more additives selected from the group consisting of BaO, Bi₂O₃, CaO, CdO, CeO₂, CoO, Cr₂O₃, Fe₂O₃, HfO₂, K₂O, La₂O₃, MgO, MnO₂, Na₂O, Nb₂O₅, Nd₂O₃, NiO, PbO, Sc₂O₃, SmO₂, SnO₂, SrO, Ta₂O₅, TiO₂, UO₂, Y₂O₃, ZnO, and ZrO₂ to be solid-solved into perovskite structures are added to the polycrystal.

Further, the method according to this invention is characterized by further comprising the steps of, prior to the adjoining of the seed single crystal to the polycrystal, predetermining the crystal orientation of the seed single crystal, grinding a specific crystal face of the seed single crystal in the crystal orientation determined, and adjoining the ground seed single crystal to the polycrystal to determine the crystal orientation of a single crystal to be grown in the polycrystal from the seed single crystal. This is based on that a single crystal to be grown in a polycrystal has the same crystal orientation as the seed single crystal.

A single crystal grown from a seed single crystal into a polycrystal has the same shape as the polycrystal. Based on this theory, the method according to this invention is characterized by further comprising the step of: prior to the adjoining of the seed single crystal to the polycrystal, molding the polycrystal powder to a desired shape or processing the polycrystal into a complex shape, and then adjoining the shaped polycrystal to the seed single crystal, to produce a single crystal having a desired complicated shape without a expensive and complex separate step for processing the single crystal.

Further, in the method according to this invention, the abnormal grain growth is induced at the interface between the seed single crystal and is repressed in the polycrystal by controlling the composition of the polycrystal, the temperature, the temperature gradient and atmosphere, etc. In addition, the porosity and the pore shape of the polycrystal is controllable depending on heating temperature, heating atmosphere (e.g., air, oxygen or vacuum), heating pressure, the amount of liquid phase and additives. And, the polycrystals of various porosities and pore shapes make it possible to produce a single crystal having various pore structures. In addition, a single crystal in the perfectly dense polycrystal can be grown into a large amount of perfectly dense single crystals free from pores. Further, single crystals of perovskite oxides, e.g., barium titanate solid solution, Pb-type perovskite such as PbTiO₃(PT), Pb(ZrₓTi₁₋ₓ)O₃(PZT), Pb(Mg_{⅓}Nb_{⅔})O₃(PMN), (1−x)PMN−xPT, Pb(Zn_{⅓}Nb_{⅔})O₃ (PZN) or (1−x)PZN−xPT, etc., or Pb-type perovskite oxide solid solution, etc. can be produced in large quantities at low costs by using a large single crystal of barium titanate having a size of more than 20×20 mm as a seed single crystal, though the produced single crystals have different compositions from that of the seed single crystal.

Hereinafter, preferred embodiments of a method according to the present invention will be described in detail.

Following Examples 1 to 8 relate to observations of abnormal grain growths induced by heating polycrystals of (1−x)Pb(Mg_{⅓}Nb_{⅔})O₃−(x)PbTiO₃ type oxides, which have a particularly excellent piezoelectric property among single crystals of Pb-type perovskite oxides, with a change of the component ratio of the polycrystal or with an addition of an extra specific component. Firstly, (1−x)Pb(Mg_{⅓}Nb_{⅔})O₃−(x)PbTiO₃ powder was prepared by the Columbite precursor method. The preparing process of the powder was as follows: magnesium niobate (MgNb₂O₆) was prepared by ball-milling magnesium carbonate hydroxide (4MgCO₃.Mg(OH)₂.4H₂O) and niobium oxide (Nb₂O₅) powders in ethanol, and then calcining them at 1100° C. for 4 hours. Finally, (1−x)Pb(Mg_{⅓}Nb_{⅔})O₃−(x)PbTiO₃ powder was prepared by mixing the calcined magnesium niobate with PbO and TiO₂ powder, ball-milling the mixture and then calcining it at 850° C. for 4 hours. (1−x)Pb(Mg_{⅓}Nb_{⅔})O₃−(x)PbTiO₃ powders having different x values in the composition formula were prepared by controlling the ratio of magnesium niobate and titanium dioxide. Powder molded bodies (the diameter: 10 mm, height: 2 mm) were prepared by uniaxial pressure molding. Then, the powder molded bodies were subjected to CIP(Cold Isostatic Pressing) at the pressure of 200 MPa. They were sintered on a platinum(Pt) plate in double platinum crucibles, and atmosphere powders such as lead zirconate (PbZrO₃[PZ]) and PbO powder were placed around the sample to repress the volatilization of PbO during sintering.

### EXAMPLE 1

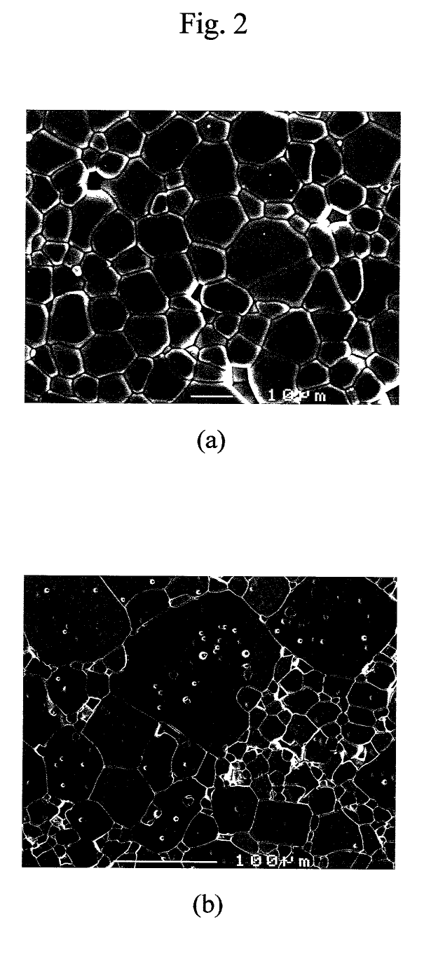

FIG. 2 is microscopic photographs of samples obtained by sintering (a) a powder molded body having the composition formula of (0.68)Pb(Mg_{⅓}Nb_{⅔})O₃−(0.32)PbTiO₃ and (b) a powder molded body having the composition formula of (0.5)Pb(Mg_{⅓}Nb_{⅔})O₃−(0.5)PbTiO₃, at 1200° C. for 10 hours. These results demonstrate that the types of grain growths are changed according to the content change of PMN and PT. A normal grain growth with a uniform distribution of grain size occurs in the case of (a), i.e., x=0.32(PMN/PT=63/32), while an abnormal grain growth occurs in the case of (b), i.e., x=0.5(PMN/PT=5/5). In other words, an abnormal grain growth occurs when x value in the composition formula of (1−x)Pb(Mg_{⅓}Nb_{⅔})O₃−(x)PbTiO₃, i.e., the ratio of PbTiO₃, is more than a specific value.

### EXAMPLE 2

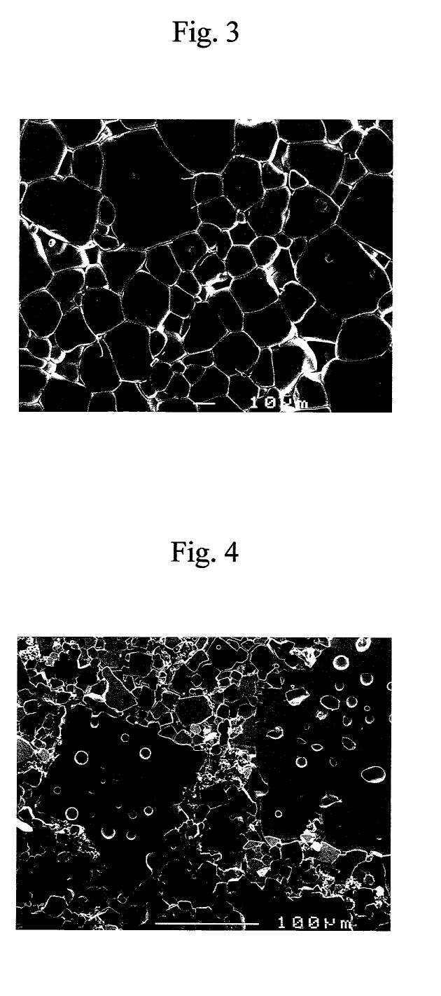

In (1−x)Pb(Mg_{⅓}Nb_{⅔})O₃−(x)PbTiO₃ type, MPB(Morphotropic Phase Boundary), which is a boundary of a tetragonal phase and a rhombohedral phase has a composition close to the composition of (0.68)Pb(Mg_{⅓}Nb_{⅔})O₃−(0.32)PbTiO₃. It was reported that the MPB composition shows an excellent piezoelectric property. In this Example, a powder having the MPB composition of (0.68)Pb(Mg_{⅓}Nb_{⅔})O₃−(0.32)PbTiO₃ was prepared by the Columbite precursor method according to Example 1. However, contrary to Example 1, excess Mg, Pb, Nb and Ti, respectively, were added during the preparation of the powder. The results were shown in FIG. 3 and FIG. 4.

FIG. 3 is a microscopic photograph of a sample obtained by sintering a powder molded body having the composition formula of (0.92)[(0.68)Pb(Mg_{⅓}Nb_{⅔})O₃−(0.32)PbTiO₃]−(0.08)MgO, at 1200° C. for 10 hours. This composition further comprises the extra MgO of 8 mol % relative to the original composition of (0.68)Pb(Mg_{⅓}Nb_{⅔})O₃−(0.32)PbTiO₃. When an excess MgO was not added or the amount of the added MgO is slight, a normal grain growth occurred. But, when an excess MgO of more than a specific amount was added, an abnormal grain growth occurred as shown in FIG. 3. The determination of whether an abnormal grain growth occurs is based on that an abnormal grain is three times as large as the average size of matrix grains and the abnormal grain shows bimodal distribution of grain size.

FIG. 4 is a microscopic photograph of a sample obtained by sintering a powder molded body having the composition formula of (0.92)[(0.68)Pb(Mg_{⅓}Nb_{⅔})O₃−(0.32)PbTiO₃]−(0.08)PbO, at 1200° C. for 10 hours. This composition further comprises the extra PbO of 8 mol % relative to the original composition of (0.68)Pb(Mg_{⅓}Nb_{⅔})O₃−(0.32)PbTiO₃. When an excess PbO was not added or the amount of the added PbO was slight, a normal grain growth occurred like the preceding FIG. 2(a). But, when an excess PbO was added, an abnormal grain growth occurred as shown in FIG. 4. As the amount of the added PbO increases, the number of the abnormal grains per unit area decreases, while the average size of the abnormal grains increases.

An abnormal grain growth did not occur when an excess Nb and Ti were added to (0.68)Pb(Mg_{⅓}Nb_{⅔})O₃−(0.32)PbTiO₃ powder, and then the powder was heated. This result demonstrates that the excess addition of only specific components among components of a polycrystal can induce an abnormal grain growth.

### EXAMPLE 3

The above Examples 1 and 2 show that an abnormal grain growth occurs when x value of the composition formula of (1−x)Pb(Mg_{⅓}Nb_{⅔})O₃−(x)PbTiO₃ type is more than a specific value, i.e., when the composition ratio of the components of the polycrystal is changed or a specific component of the polycrystal such as MgO or PbO is added in excess. This Example relates to the observation of the behaviors of the grain growths occurring when the Mg contents of a powder are higher or lower than that of the original composition of (0.68)Pb(Mg_{⅓}Nb_{⅔})O₃−(0.32)PbTiO₃ powder to which an excess PbO was added. (0.68)Pb(Mg_{⅓}Nb_{⅔})O₃−(0.32)PbTiO₃ powders were prepared by the above Examples 1 and 2. The Mg contents of the powders are controlled from 15% Mg-deficient content to 15% Mg-extra content.

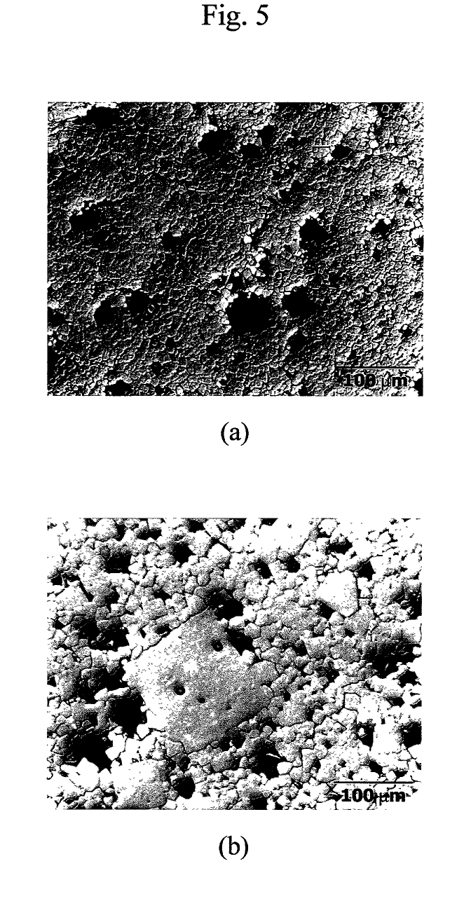

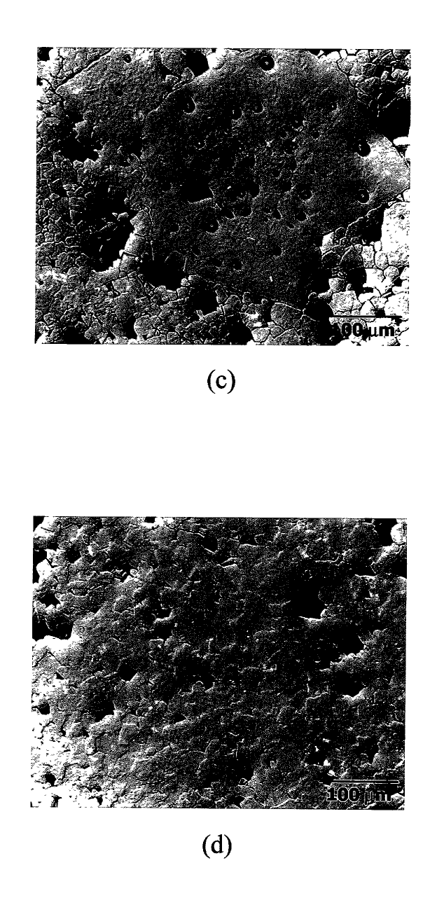

FIG. 5 is microscopic photographs of samples obtained by sintering powder molded bodies, which are (a) 2% Mg-deficient (−2 Mg), (b) 1% Mg-deficient (−1 Mg), (C) 0% Mg-deficient (0 Mg) and (d) 1% Mg-extra (1 Mg) in the composition formula of (0.92)[(0.68)Pb(Mg_{⅓}Nb_{⅔})O₃−(0.32)PbTiO₃]−(0.08)PbO, at 1200 ° C. for 10 hours.

Under the above respective condition, the powders were heated. As a result, abnormal grain growths were observed only in the case of (b) and (c). In other words, abnormal grain growths were observed in the case of 1% Mg-deficient composition and 0% Mg-deficient composition. But, abnormal grain growth did not occur and growth of matrix grains was very limited, when the Mg content was more deficient than 1% such as (a). Thus, both abnormal grain growths and matrix grain growths are repressed when the Mg content is lower than a specific value, i.e., the Nb content is excess. But, when an excess Mg was added such as in (d), according as the number of the grown abnormal grains increased, the sizes of the grains decreased, while the growth of matrix grains was promoted, thus the result showed an uniform distribution of grain sizes.

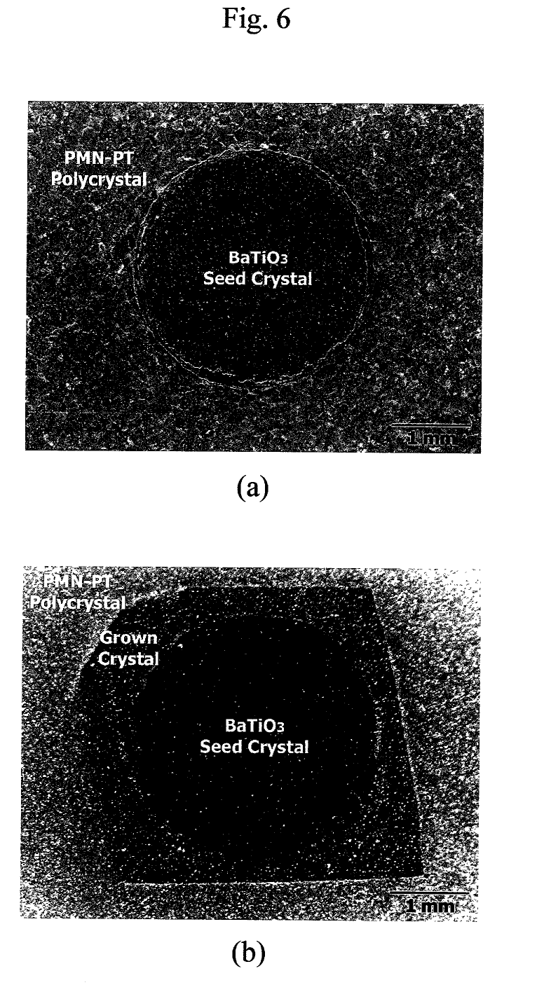

A seed single crystal of BaTiO₃ was placed in said powders of FIG. 5, followed by being heated at 1200° C. for 10 hours (FIG. 6). In FIG. 6(a), i.e., a composition of which the Mg content is more than 1% deficient, both an abnormal grain growth and a seed single crystal growth did not occur. In the samples of FIG. 5(b) and 5(c), an abnormal grain growth and a seed single crystal growth occurred with showing large size differences between the abnormal grains and the matrix grains. However, the abnormal grains blocked the seed single crystal growth when the abnormal grains met the seed single crystal. Therefore, the seed single crystal could not grow to more than a specific size and captured the abnormal grains. As a result, the quality of the seed single crystal became deteriorated. In FIG. 6(b), i.e., a composition of which the Mg content is more than 1% excess, the seed single crystal rapidly grew and the entire grain size distribution was uniform and the sizes of the abnormal grains were small. Thus, the abnormal grains did not block the seed single crystal growth, and the abnormal grains were not captured into the seed single crystal. Therefore, preferably, both MgO and PbO of more than a specific amount must be added, so as to grow effectively PMN-PT single crystal of MPB composition.

### EXAMPLE 4

A growth rate of a seed single crystal in a polycrystal largely depends on the crystal orientation of the seed single crystal. In this example, (0.92)[(0.68)Pb(Mg_{⅓}Nb_{⅔})O₃−(0.32)PbTiO₃]−(0.08)PbO powder further comprising 1% excess Mg was prepared as shown in Example 3 and then a seed single crystal of BaTiO₃, which is a plate-shaped crystal having a different crystal orientation, was placed in the powder, followed by being heated.

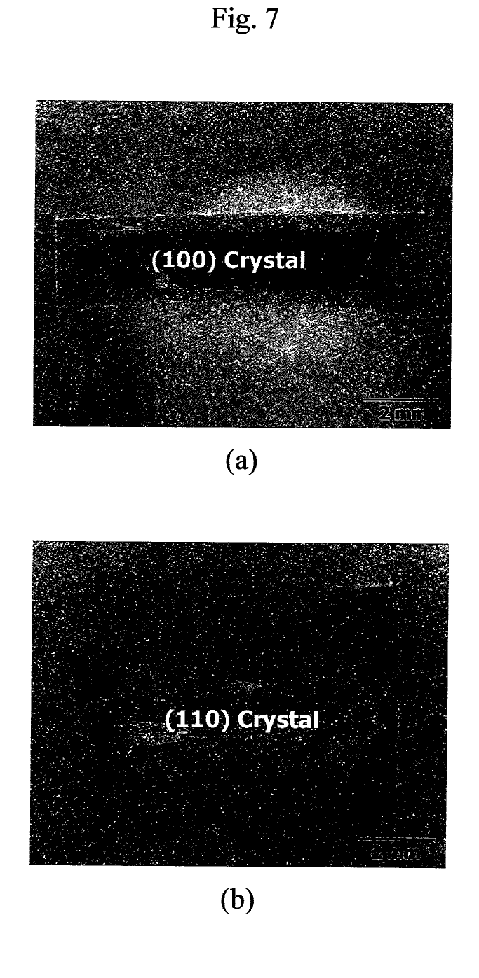

FIG. 7 is microscopic photographs of PMN-PT single crystals grown from samples obtained by embedding a seed single crystal of BaTiO₃, which is a plate-shaped crystal of (a) (100) side, (b) (110) side and (c) (111) side, in powder molded bodies further having 1% extra Mg (1 Mg) in addition to the original Mg content in the composition formula of (0.92)[(0.68)Pb(Mg_{⅓}Nb_{⅔})O₃−(0.32)PbTiO₃]−(0.08)PbO, and then heating the combination at 1200° C. for 10 hours. The photographs show the interface between the seed single crystal of BaTiO₃ and the grown PMN-PT single crystal. As shown in the photographs, though a single crystal of BaTiO₃ has a different composition from PMN-PT single crystal, the single crystal of BaTiO₃ functions as a seed single crystal to grow a PMN-PT crystal. The reason is that a single crystal of BaTiO₃ can continue to grow into a PMN-PT polycrystal because it is chemically stable in PbO-based liquid phase and the lattice constant thereof is similar to that of PMN-PT. In FIG. 7(a), which used a single crystal of BaTiO₃ being a plate-shaped crystal of (100) side as a seed single crystal, the growth side maintains (100) side while the growth rate was very low such as 20 μm/h. But, when single crystals of BaTiO₃ of (110) side and (111) side were used as a seed single crystal, the growth rate is higher than that of (100) side such as 100 to 300 μm/h. However, a triangle-shaped single crystal grew because the growth side could not be maintained, when (111) side was used. Thus, in this case, wide PMN-PT single crystal could not be produced. When (110) side was used, the growth rate is high and wide PMN-PT single crystal could be produced.

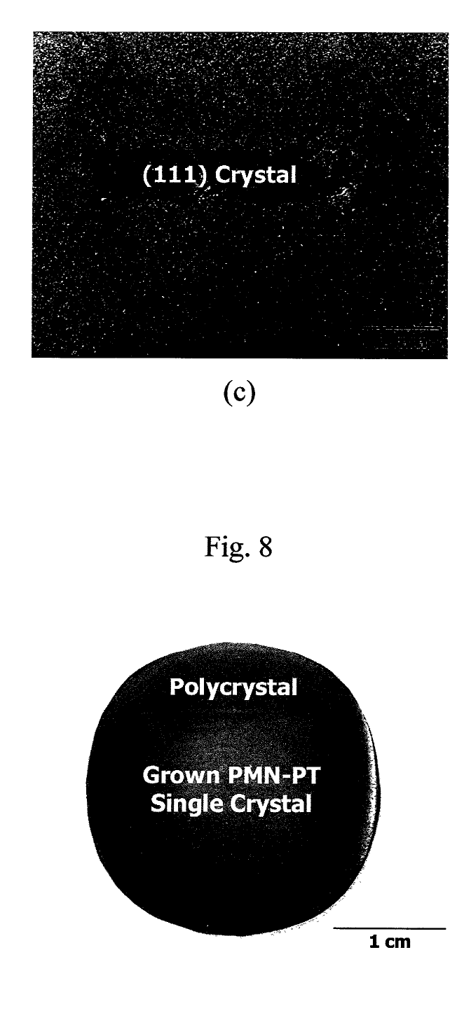

FIG. 8 is a microscopic photograph of a PMN-PT single crystal (diameter: 1.5 cm) grown from samples obtained by embedding a seed single crystal of BaTiO₃ in powder molded bodies further having 1% extra Mg (1 Mg) in addition to the original Mg content in the composition formula of (0.92)[(0.68)Pb(Mg_{⅓}Nb_{⅔})O₃−(0.32)PbTiO₃]−(0.08)PbO, and then heating the combination at 1200° C. for 20 hours. This photograph shows a PMN-PT single crystal having a diameter of more than 1.5 cm in the middle of the sample surface. This demonstrates that a PMN-PT single crystal having a diameter of more than 1.5 cm can be produced by short heat treatment of only 20 hours. Further, a PMN-PT single crystal growth from a seed single crystal could be observed, when a plate-shaped seed single crystal of barium titanate was placed on a powder sintered body of (0.92)[(0.68)Pb(Mg_{⅓}Nb_{⅔})O₃−(0.32)PbTiO₃]−(0.08)PbO, followed by being heated at 1200° C. for 20 hours. Therefore, a seed single crystal could rapidly grow into a polycrystal when the seed single crystal was placed on the powder molded body, as well as being embedded in the powder molded body. The use of a seed single crystal such as “ [symbol] ”-shaped crystal enables a faster single crystal growth than that of a plate-shaped single crystal, because the interface between the seed single crystal and the polycrystal is increased and thus the number of the growth faces is increased.

The above Examples 1 to 4 demonstrate that an abnormal grain growth can occur in (1−x)Pb(Mg_{⅓}Nb_{⅔})O₃−(x)PbTiO₃ type when x value of the composition formula is more than a specific value, i.e., the component ratio of the polycrystal is changed, or an excess specific component such as PbO or MgO are added. In other words, the behavior of an abnormal grain growth can be changed according to the ratio of Pb, Mg, Nb and Ti and additives. Therefore, the method for optimizing the growth of a PMN-PN single crystal is to change the composition ratio of the respective components of PMN-PN and to add an excess specific component. The single crystals of PMN-PT produced by these manners can be used as a seed single crystal, in order to produce various single crystals of (1−x)PMN−xPT, which have same components as one another, but have different PMN/PT from one another at low costs.

### EXAMPLE 5

The regulation of powder compositions (the ratio of the components, the kind and content of an additive), sintering temperature, sintering atmosphere(air, oxygen or vacuum), pressure sintering, the amount of a liquid state, atmospheric powders and the sealing state of a crucible, which effect the densification of a sintered body of Pb-type perovskite oxides, enables the change of the porosity and pore shape of the sintered body. The porosity and pore shape of a polycrystal directly affect the porosity and pore shape of a grown single crystal, because the pores of the polycrystal are trapped in the single crystal during the growth of the single crystal. Therefore, if the porosity of a polycrystal is controlled, single crystals without pores, single crystals with pores, or single crystals having various pore sizes or shapes can be produced.

Following Table 1 shows the relative densities of the sintered bodies produced by adding an excess PbO and MgO to (0.68)Pb(Mg_{⅓}Nb_{⅔})O₃−(0.32)PbTiO₃ powder having MPB composition, followed by sintering the powder at 1200° C. for 1 hour.

TABLE 1

| | PbO | | |
|---|---|---|---|
| MgO | 0 | 2 | 8 |
| 0 | 98 | 96 | 93 |
| 1 | 97 | 97 | 94 |
| 8 | 97 | 98 | 94 |

As shown in Table 1, an excess MgO and PbO were added to the (0.68)Pb(Mg_{⅓}Nb_{⅔})O₃−(0.32)PbTiO₃ powder and then the powder was heated. As a result, it was observed that the microstructure such as the density and grain size of the sintered body changed continuously. The relative density of the sintered body without an addition of MgO or PbO was about 98%, but the relative density with an excess addition of 8mol % PbO was reduced to 93%. According to the increase of the addition amount of PbO, the density of the sintered body was continuously reduced and the pore size was increased. But, according to the increase of the addition amount of MgO, the density of the sintered body was gradually increased and the pore size was reduced, unlike PbO. When an excess MgO was not added or the excess addition amount of MgO was not large, PMN-PT single crystal could be grown from a seed single crystal only in a composition to which many excess PbO were added. The produced single crystal had a low density of about 94%, since the density of the polycrystal was low. But, when the excess addition amount of MgO was large, PMN-PT single crystal could be grown from a seed single crystal even in a composition to which a little PbO was added. The produced single crystal had a density of more than 97%, since the density of the polycrystal was high.

The production of a polycrystal having a high relative density of more than 99% was carried out by pressure-sintering the powders having the composition of Table 1 at the pressure of 50 Mpa in vacuum, for densification. The composition to which the small amount of excess PbO is added can be more easily densified than the case of the large amount. But, in this case, the seed single crystal was not grown or the growth rate was less than 50 μm/h, which is too late. However, when sufficient excess PbO and MgO were added to the polycrystal, a single crystal having a high relative density of more than 99% could be produced. Further, the production of a very dense PMN-PT single crystal could be carried out by primarily pressure-sintering a polycrystal to prepare a sintered body having a high density, and then secondly heating the adjoined combination of the compacted polycrystal and a seed single crystal of barium titanate. PMN-PT single crystals having a desired various porosities, e.g., a single crystal comprising pores of several % or a perfectly dense single crystal, can be produced according to this method in large quantities at low costs.

### EXAMPLE 6

In this Example, the production of PZT single crystal was carried out by changing the component ratio of Pb(ZrₓTi₁₋ₓ)O₃(PZT), which is most generally used as a piezoelectric material, or by adding a specific component of PZT or an additive to the PZT, in order to induce an abnormal grain growth. The preparation of PZT powders was carried out by ball-milling PbO, ZrO₂ and TiO₂ powders in ethanol and then by calcining the powders at 800° C. for 4 hours. Further, Pb(ZrₓTi₁₋ₓ)O₃ powders having various x values were produced by the control of the rate of ZrO₂ and TiO₂. Powder molded bodies (diameter: 10 mm, height: 3 mm) were produced by uniaxial pressure molding, and then the produced power molded bodies were subjected to CIP(Cold Isostatic Pressing) at the pressure of 200 MPa. Then, they were sintered on a platinum plate in double platinum crucibles, and atmospheric powders such as lead zirconate (PbZrO₃[PZ]) and PbO powder were placed around the sample to repress the volatilization of PbO during sintering.

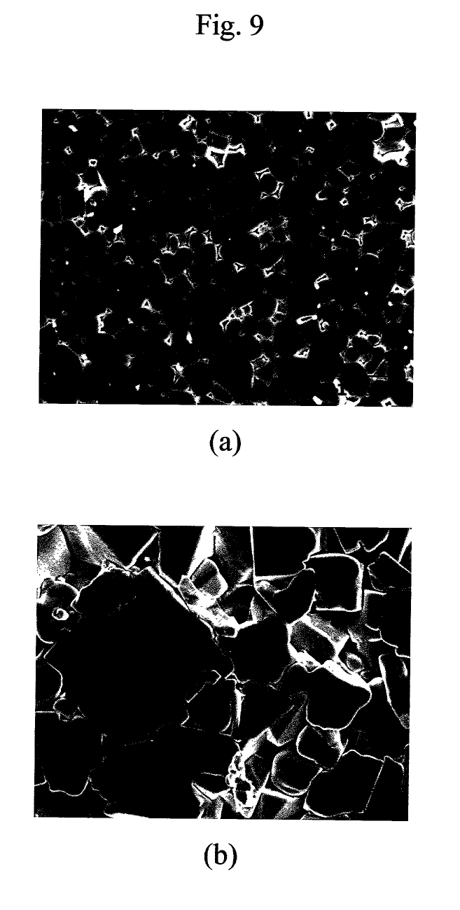

FIG. 9 is microscopic photographs of samples obtained by sintering powder molded bodies having x value of (a) 0.6 and (b) 0.25 in the composition formula of (0.9)[Pb(ZrₓTi₁₋ₓ)O₃]−(0.1)PbO, at 1200° C. for 3 hours. When x=0.6 (a), a normal grain growth having a uniform grain size distribution took place. But, when the PT content was more than a specific amount, e.g., the composition in which x=0.25 (b), an abnormal grain growth occurred under the addition condition of excess PbO. Therefore, it was demonstrated that an abnormal grain growth occurs when excess PbO is added to a specific composition of [Pb(ZrₓTi₁₋ₓ)O₃] in which x, i.e., the composition rate of PbTiO₃ is higher than a specific value.

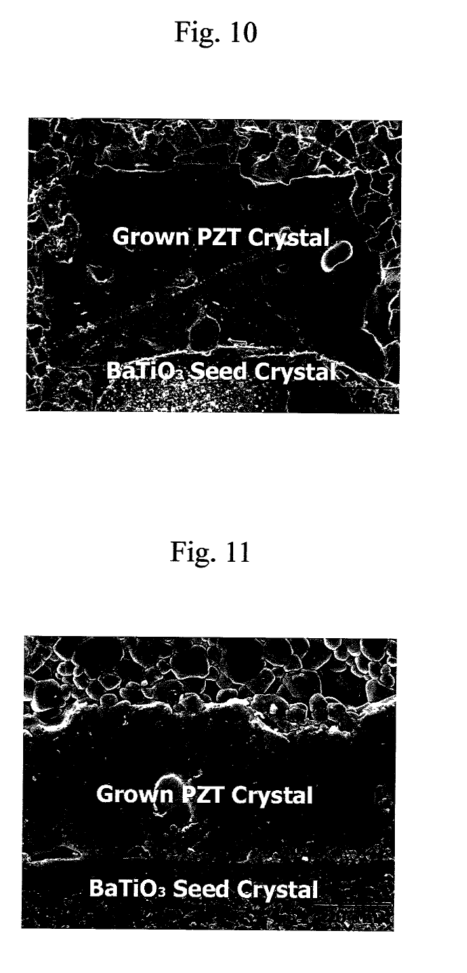

FIG. 10 is a microscopic photograph a sample obtained by embedding a seed single crystal of BaTiO₃ in a powder molded body having the composition formula of (0.9)[Pb(Zr_{0.25}Ti_{0.75})O₃]−(0.1)PbO, and then sintering the combination at 1200° C. for 10 hours. When the composition rate of PbZrO₃, i.e., x value was more than a specific value, an abnormal grain growth and seed single crystal growth were not occurred. But, when x=0.25 (FIG. 10), both an abnormal grain growth and a seed single crystal growth occurred.

FIG. 11 is a microscopic photograph a sample obtained by embedding a seed single crystal of BaTiO₃ in a powder molded body having the composition formula of (0.9)[Pb(Zr_{0.6}Ti_{0.4})O₃]−(0.1)[(0.95)PbO−(0.05)Cr₂O₃], and then sintering the combination at 1200° C. for 10 hours. When Cr₂O₃ as well as the PZT components, i.e., PbO, ZrO₂ and TiO₂ are added to the PZT in which x=0.6, abnormal grain growths were promoted and the seed single crystal was grown.

In this Example, it was demonstrated that an abnormal grain growth in Pb(ZrₓTi₁₋ₓ)O₃ (PZT) depends on an increase of the PbTiO₃ content of PZT powder and an addition of additives, e.g., PbO, B₂O₂, CoO, Cr₂O₃, Fe₂O₃, SiO₂, MnO, MoO₃, Nb₂O₅, NiO, V₂O₅, WO₃ or ZnO. If x value is too large in Pb(ZrₓTi₁₋ₓ)O₃ to show an abnormal grain growth, an addition of additives for induction of an abnormal grain growth enables an abnormal grain growth and the seed single crystal growth. If x value is so small that abnormal grain growths over-occur, an addition of additives for repression of an abnormal growth enables the control of an abnormal grain growth and the seed single crystal growth.

According to the present invention, the production of PZT single crystal was carried out by controlling the ratio of Pb, Zr and Ti in the composition formula of Pb(ZrₓTi₁₋ₓ)O₃ or adding an additive for induction or repression of abnormal grain growths, followed by heating. In this method, the size of PZT single crystal is in proportion to the size of the seed single crystal. For example, PZT single crystal having a size of more than several cm can be produced in large quantities at low costs by using a seed single crystal having a size of more than several cm.

### EXAMPLE 7

In this example, in order to induce an abnormal grain growth in Pb(ZrₓTi₁₋ₓ)O₃, power molded bodies were produced by mixing Pb(Zr_{0.52}Ti_{0.48})O³ powder having the size of 100 nm with PbZrO₃ powder. Powder molded bodies (diameter: 10 mm, height: 3 mm) were produced by uniaxial pressure molding, and then the produced power molded bodies were subjected to CIP(Cold Isostatic Pressing) at the pressure of 200 MPa. Then, they were sintered on a platinum plate in double platinum crucibles, and lead zirconate (PbZrO₃[PZ]) as an atmospheric powder was placed around the sample to repress the volatilization of PbO during sintering.

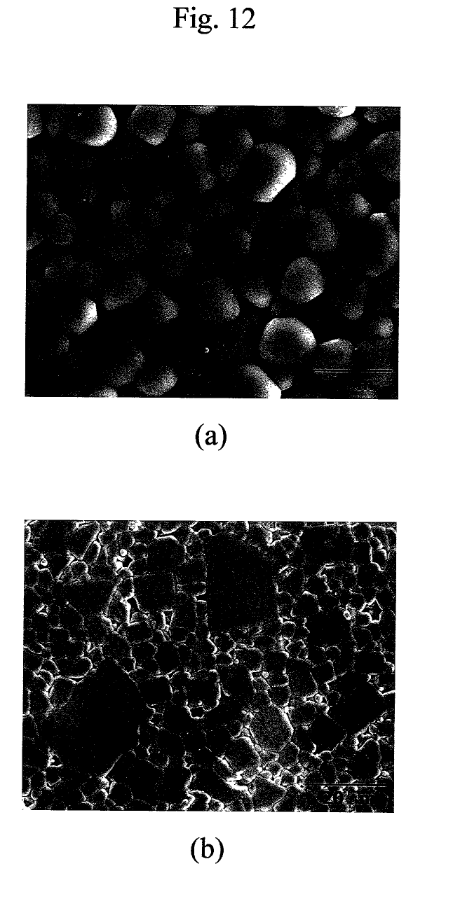

FIG. 12 is microscopic photographs of samples obtained by sintering powder molded bodies having the composition formula of (a) Pb(Zr_{0.52}Ti_{0.48})O₃ and (b) (0.7)Pb(Zr_{0.52}Ti_{0.48})O₃−(0.3)PbZrO₃, at 1200° C. for 1 hour. An abnormal grain growth did not occur in Pb(Zr_{0.52}Ti_{0.48})O₃ composition, but began to occur with an addition of more than specific amount of PbZrO₃ and very actively occurred with an addition of more than 30 mol % of PbZrO₃.

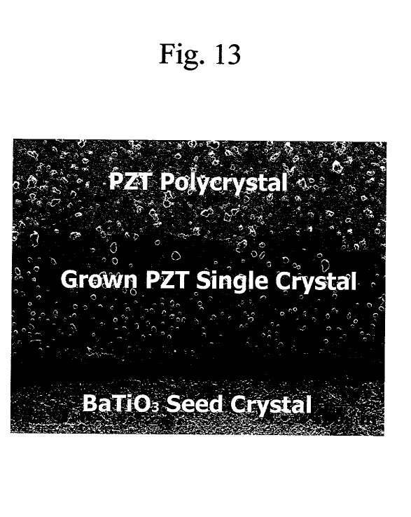

FIG. 13 is a microscopic photograph of a sample obtained by embedding a seed single crystal of BaTiO₃, which is a plate-shaped crystal of (111) side, in a powder molded body having the composition formula of (0.8)[Pb(Zr_{0.52}Ti_{0.48})O₃]−(0.2)PbZrO₃, and then heating the combination at 1200° C. for 10 hours. In the composition to which PbZrO₃ is added in small amount, e.g., FIG. 12(a), both an abnormal grain growth and a seed single crystal growth did not occur. But, in the composition to which PbZrO₃ is added in more than a specific amount inducing an abnormal grain growth, e.g., FIG. 13, the same structure as the seed single crystal was continuously grown into the PZT polycrystal and PZT single crystal was obtained.

When a grain growth was promoted in Pb(ZrₓTi₁₋ₓ)O₃ (PZT) by a powder having a nano size, an abnormal grain growth occurred with an addition of PbZrO₃ and the seed single crystal was grown. The use of a powder having a nano size in the present method enables an abnormal grain growth and the production of PZT having a large x value.

### EXAMPLE 8

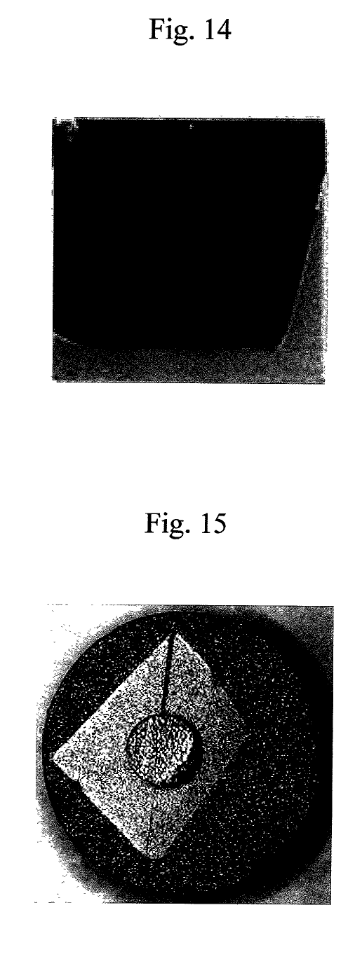

FIG. 14 is a microscopic photograph showing the appearance of a sample prepared with a small seed single crystal of barium titanate (diameter: 3 mm, thickness: 1.5 mm) placed on the edge of a polycrystal of barium titanate, which was prepared by pressing a powder molded body (25 g) having the size of 40×40×7 cm at 200 MPa, and subjected to 300 hours of heat treatment with a temperature gradient such that the temperature is 1350° C. on the side of the seed single crystal and decreased to a temperature slightly below 1350° C. on the opposite edge side of the sample. The temperature gradient had the polycrystal side be in less than the second abnormal grain growth activation temperature, thus an abnormal grain growth did not occur in the polycrystal. But, the same structure as the seed single crystal, which initiated the growth at less than the second abnormal grain growth activation temperature, continued to grow into the polycrystal and thus a single crystal having a size of more than length 25 mm×width 25 mm×height 5 mm was produced

This example demonstrates that the formation of a temperature gradient, which have the temperature of a seed single crystal high and the temperature of a polycrystal low, in the adjoined combination of the seed single crystal and the polycrystal, enables the growth of a single crystal.

### EXAMPLE 9

FIG. 15 is a microscopic photograph showing the appearance of a sample prepared with a single crystal of barium titanate including a (111) double twin plate placed on a polycrystal of barium titanate (diameter: 15 mm, height; 7 mm) and subjected to 15 hours of a heat treatment at 1350° C. When a single crystal of barium titanate comprising a defect such as a (111) double twin plate was used as a seed single crystal, the single crystal grown from the seed single crystal also comprised a (111) double twin plate as shown in FIG. 15. In this case, the growth rate of the single crystal with a defect was faster than that of the single crystal without a defect in the polycrystal. Therefore, this example demonstrated that a defect such as a (111) double twin plate promotes the growth of a single crystal into a polycrystal. In this example, a small single crystal of barium titanate including a (111) double twin plate was adjoined to a polycrystal of barium titanate. As a result, a large single crystal of barium titanate could be produced and a larger single crystal of barium titanate could be rapidly produced using the produced large single crystal of barium titanate with a (111) double twin plate as a seed single crystal.

### EXAMPLE 10

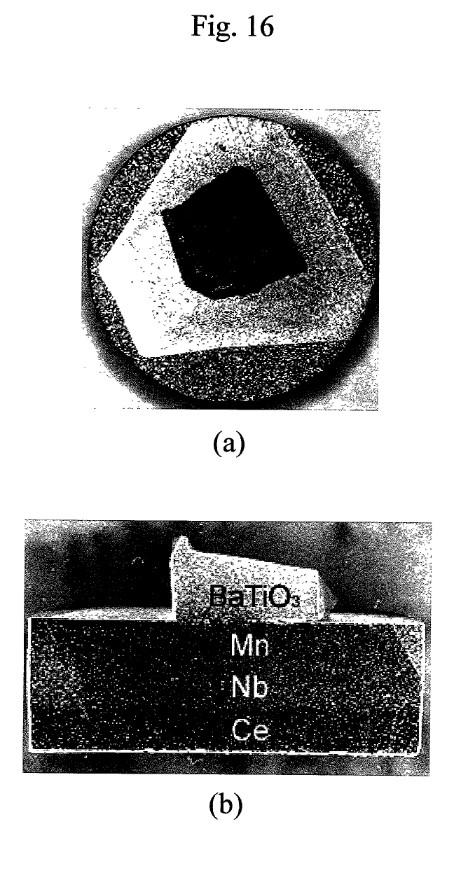

FIG. 16 is microscopic photographs showing the surface (a) and the cross section (b) of a sample prepared by placing a single crystal of barium titanate on a molded body and then heating at 1350° C. for 50 hours, wherein the molded body is formed by laminating in a row three powders(each thickness: 1.5 mm) having the composition formulas of (99.9)BaTiO₃−(0.1)MnO₂(mol %); (99.9)BaTiO₃−(0.1)NbO_{2.5}(mol %); and (99.9)BaTiO₃−(0.1)CeO₂(mol %) and then subjecting to CIP at 200 MPa. Firstly, the seed single crystal of barium titanate began to grow into the layer comprising MnO₂. Then, it continued to grow into the layer comprising NbO_{2.5} and CeO₂. As a result, a single crystal of barium titanate solid solution with a continual composition variation, which is composed of four layers, i.e., undoped barium titanate, Mn solid solution, Nb solid solution and Ce solid solution was produced. As described above, the SSCG method is more advantageous than the general LSCG method in that the SSCG method enables the production of a single crystal having a composition gradient unlike the LSCG method.

As described above, the method for growing single crystals of perovskite oxides according to the present invention has some advantages to provide a manufacturing process for single crystals such as undoped single crystals of barium titanate, single crystals of barium titanate solid solution, single crystals of Pb-type perovskite and single crystals of Pb-type perovskite solid solution by using a general and simple heat treatment method without special equipments or skilled functions, as a result of which a large amount of single crystals large enough for practical uses of more than several cm can be produced at a low cost. The method also enables production of single crystals having various additive contents by using a sintered body of the polycrystal with various additives added thereto. This method for growing single crystals of barium titanate and barium titanate solid solutions according to the present invention allows a growth of single crystals without a limitation in the size of the single crystal and provides high reproducibility of the single crystals with a composition gradient. The method also makes it possible to control the porosity of the single crystal, and the size and shape of pores, and prepare a complex single crystal from a polycrystal of a desired shape adjoined to the seed single crystal by heat treatment without a complicate step of processing a single crystal. This method of the present invention is efficient in the economical aspect because the final single crystals can be reused as a seed single crystal to produce various seed single crystals at a low cost, and also applicable to other systems showing an abnormal grain growth as well as barium titanate, barium titanate solid solutions, Pb-type perovskite and Pb-type perovskite solid solution.

What is claimed is:

1. A method for growing single crystals of perovskite oxides, which show abnormal grain growths by means of heating, the method comprising the steps of:
(a) having a perovskite seed single crystal adjoined to a perovskite polycrystal; and
(b) heating the combination of the seed single crystal and the polycrystal to provide a continuous growth of the same structure as the seed single crystal in the polycrystal, the heating being carried out under the condition that abnormal grain growths are induced at the interface between the polycrystal and the seed single crystal and are repressed inside the polycrystal.

2. The method as claimed in claim 1, wherein the heating of said step (b) is carried out under the condition that the ratio of the components of the perovskite polycrystal is controlled.

3. The method as claimed in claim 1, wherein the heating of said step (b) is carried out under the condition that specific components of the perovskite polycrystal are added in excess of the original composition.

4. The method as claimed in claim 1, wherein the heating of said step (b) is carried out under the condition that a temperature gradient is formed such that the temperature of the single crystal side is high and the temperature of the polycrystal side is low.

5. The method as claimed in claim 1, wherein the heating of said step (b) is carried out under the condition that additives for promoting abnormal grain growths are locally added to the combination of the seed single crystal and the polycrystal.

6. The method as claimed in claims 2 or 3, wherein the polycrystal is a Pb-type perovskite polycrystal in which abnormal grain growths occur by a change of the ratio of the components or an excess addition of specific components.

7. The method as claimed in any one of claims 1 to 5, wherein the step (a) includes placing the seed single crystal on the polycrystal or a powder molded body of perovskite oxides; or embedding the seed single crystal in the powder, and then performing a molding process; or adjoining the polycrystal to the seed single crystal, and then embedding the combination of the polycrystal and the seed single crystal in the powder and then performing a molding process.

8. The method as claimed in any one of claims 1 to 5, wherein the seed single crystal of the step (a) is the perovskite single crystal produced by the said methods.

9. The method as claimed in claim 6, wherein the seed single crystal is a single crystal of barium titanate or perovskite having the same crystal structure as barium titanate.

10. The method as claimed in any one of claims 1 to 5, further comprising the step of:
prior to the step (a), predetermining the crystal orientation of the seed single crystal, grinding a specific crystal face of the seed single crystal in the crystal orientation determined, and adjoining the ground seed single crystal to the polycrystal to determine the crystal orientation of a single crystal to be grown into the polycrystal from the seed single crystal.

11. The method as claimed in any one of claim 1 to 5, further comprising the step of: prior to the step (a), molding the polycrystal powder to a desired shape or processing the polycrystal into a complex shape, and then adjoining the shaped polycrystal to the seed single crystal, to produce a single crystal having a desired shape without a separate step for processing of the single crystal.

12. The method as claimed in any one of claim 1 to 5, further comprising the step of: prior to the step (a), preparing a polycrystal having a different porosity, pore size and pore shape by adding an additive to the polycrystal, changing the amount of a liquid phase or the sintering temperature, atmosphere or pressure of the polycrystal, to control the porosity, the pore size and shape in the single crystal to be grown in the polycrystal, thereby preparing perfectly dense single crystals destitute of pores or single crystals having various porosities.

13. The method as claimed in any one of claim 1 to 5, the perovskite polycrystal of the step (a) is the polycrystal having a composition gradient that changes discontinuously or continuously by adding one or more selected from the group consisting of solutes to be solved into perovskite structures to the perovskite polycrystal.

14. The method as claimed in any one of claim 1 to 5, wherein the seed single crystal of the step (a) is a single crystal of barium titanate including a (111) double twin to provide the polycrystal adjoined to the (111) double twin plate.

15. The method as claimed in any one of claim 1 to 5, the heating temperature of the step (b) is slightly lower than the secondary abnormal grain growth activating temperature of the combination of the seed single crystal and the polycrystal.

16. The method as claimed in any one of claims 1 to 5, the perovskite polycrystal is characterized in that one or more additives selected from the group consisting of BaO, Bi₂O₃, CaO, CdO, CeO₂, CoO, Cr₂O₃, Fe₂O₃, HfO₂, K₂O, La₂O₃, MgO, MnO₂, Na₂O, Nb₂O₅, Nd₂O₃, NiO, PbO, Sc₂O₃, SmO₂, SnO₂, SrO, Ta₂O₅, TiO₂, UO₂, Y₂O₃, ZnO, and ZrO₂ to be solid-solved into perovskite structures are added to the polycrystal.

17. The method as claimed in any one of claim 1 to 5, the seed single crystal of the step (a) has a plate-shape or “ [symbol] ”-shape.

18. The method as claimed in claim 5, the additives are one or more selected from the group consisting of Al₂O₃, B₂O₃, CuO, GeO₂, Li₂O₃, P₂O₅, PbO, SiO₂ and V₂O₅.

19. The method as claimed in claim 6, the Pb-type perovskite polycrystal is (1−x)[Pb(Mg_{⅓}Nb_{⅔})O₃]−x[PbTiO₃](023 x≦1) (PMN-PT) polycrystal.

20. The method as claimed in claim 19, the heating is carried out under the condition that at least one of PbO and MgO, which are components of the polycrystal, are added in excess of the composition formula.

21. The method as claimed in claim 6, the Pb-type perovskite polycrystal is Pb(ZrₓTi₁₋ₓ)O₃(0≦x≦1)(PZT) polycrystal.

22. The method as claimed in claim 21, the heating is carried out under the condition that PbO of a component of the polycrystal is added in excess of the composition formula.

23. The method as claimed in claim 21, the heating is carried out by using Pb(ZrₓTi_{1-x)O}³ powder particles having nano sizes.
